(19) United States
(12) Patent Application Publication
(10) Pub. No.: US 2019/0101568 A1
(43) Pub. Date: Apr. 4, 2019

(54) PROBE ASSEMBLY AND CAPACITIVE PROBE THEREOF

(71) Applicant: CHUNGHWA PRECISION TEST TECH. CO., LTD., Taoyuan City (TW)

(72) Inventors: CHIH-PENG HSIEH, TAIPEI CITY (TW); WEI-JHIH SU, TAICHUNG CITY (TW)

(21) Appl. No.: 15/859,273

(22) Filed: Dec. 29, 2017

(30) Foreign Application Priority Data
Sep. 29, 2017 (TW) 106133738

(51) Int. Cl. G01R 1/067; G01R 1/073; G01R 31/28

(52) U.S. Cl. CPC G01R 1/06711; G01R 31/2886; G01R 1/07342

(57) ABSTRACT

The instant disclosure provides a probe assembly and a capacitive probe thereof. The capacitive probe includes a probe structure, a conductive structure and a dielectric structure. The probe structure includes a first end portion, a second end portion corresponding to the first end portion, and a connecting portion connected between the first end portion and the second end portion. The conductive structure is disposed on one side of the probe structure. The dielectric structure is disposed between the probe structure and the conductive structure.

### BACKGROUND

### 1. Technical Field

The instant disclosure relates to a probe assembly and a capacitive probe thereof, and in particular, to a probe assembly and a capacitive probe thereof for a chip probe card.

### 2. Description of Related Art

When performing high-speed signal tests, the core power of a conventional System on Chip (SoC) often has a target impedance value at the used frequency point that is too high. Such a problem may be related to the probe card, the transfer substrate, the probe seat or the chip probe. Therefore, the existing solution mostly focuses on the optimization of the transfer substrate, i.e., using a suitable number of decouple capacitors to improve the target impedance value of the power delivery network (PDN). However, even if such an approach can allow the transfer substrate to have a desired impedance value, the distance between the transfer substrate and the end to be measured is too large and hence, the overall power delivery network cannot be effectively controlled.

Therefore, there is a need in the art to provide a probe assembly and a capacitive probe thereof which are able to reduce the power impedance at the resonant frequency point when performing high speed system on chip application tests and to increase the performance of the power delivery network for overcoming the above disadvantages.

### SUMMARY

The object of the instant disclosure is to provide a probe assembly and a capacitive probe thereof for effectively reducing the power impedance of the resonant frequency point and increasing the performance of the power delivery network.

An embodiment of the instant disclosure provides a capacitive probe including a probe structure, a conductive structure and a dielectric structure. The probe structure has a first end portion, a second end portion corresponding to the first end portion, and a connecting portion connected between the first end portion and the second end portion. The conductive structure is disposed at one side of the probe structure. The dielectric structure is disposed between the probe structure and the conductive structure.

Another embodiment of the instant disclosure provides a probe assembly including a transfer board, a probe carrying seat and a plurality of capacitive probes. The transfer board has a plurality of accommodating grooves, and the probe carrying seat is disposed on the transfer board. The plurality of capacitive probes are disposed on the probe carrying seat and respectively in the plurality of accommodating grooves, in which each of the capacitive probes includes a probe structure, a conductive structure and a dielectric structure. The conductive structures of each of the capacitive probes are electrically connected to the transfer board. The probe structure has a first end portion, a second end portion corresponding to the first end and a connecting portion connected between the first end portion and the second end portion. The conductive structure is disposed at one side of the probe structure, and the dielectric structure is disposed between the probe structure and the conductive structure.

One of the advantages of the instant disclosure resides in that the probe assembly and the capacitive probe thereof can optimize the target impedance value and increase the performance of the power delivery network based on the technical feature of “the dielectric structure is disposed between the probe structure and the conductive structure”.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1 is an exploded perspective view of a capacitive probe of a first embodiment of the instant disclosure.

FIG. 2 is an assembly perspective view of the capacitive probe of the first embodiment of the instant disclosure.

FIG. 3 is a sectional side schematic view taken along line in FIG. 1.

FIG. 4 is a schematic cross-sectional view taken along line IV-IV in FIG. 2.

FIG. 5 is a schematic cross-sectional view of another implementation of the capacitive probe of the first embodiment of the instant disclosure.

FIG. 6 is an exploded perspective view of a capacitive probe of a second embodiment of the instant disclosure.

FIG. 7 is an assembly perspective view of the capacitive probe of the second embodiment of the instant disclosure.

FIG. 8 is a schematic cross-sectional view taken along line VIII-VIII in FIG. 6.

FIG. 9 is a schematic cross-sectional view taken along line IX-IX in FIG. 7.

FIG. 10 is a schematic cross-sectional view of another implementation of the capacitive probe of the second embodiment of the instant disclosure.

FIG. 11 is an exploded schematic view of a probe assembly of a third embodiment of the instant disclosure.

FIG. 12 is an assembly schematic view of the probe assembly of the third embodiment of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

It is noted that the term “first” and “second” for describing different elements or signals are only used to distinguish these elements/signals from one another rather than limiting the nature thereof. In addition, the term “or” used in the specification may include one or more of the listed items.

### First Embodiment

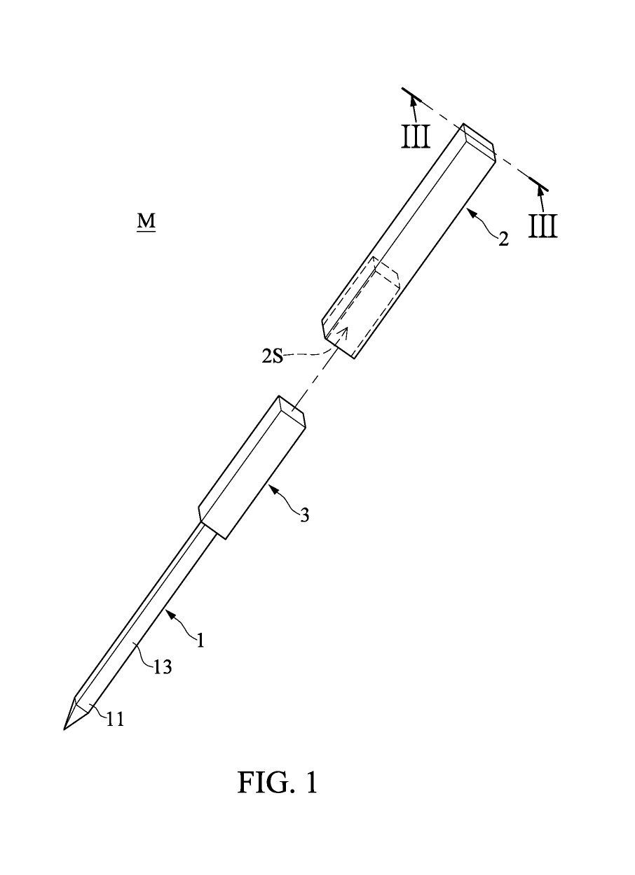

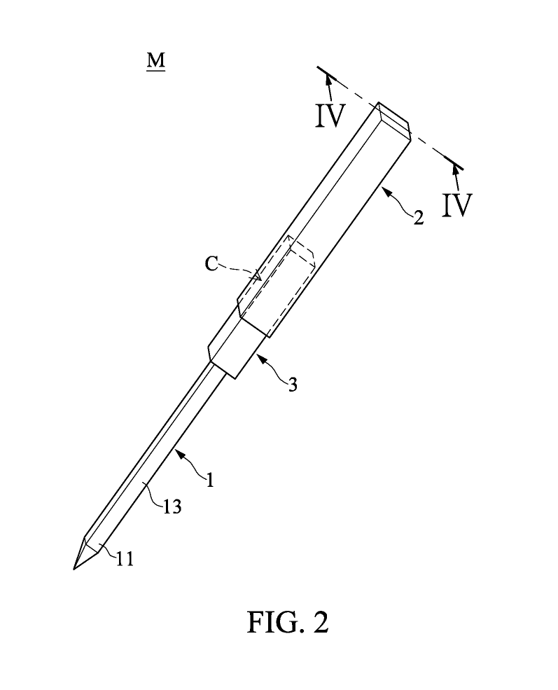

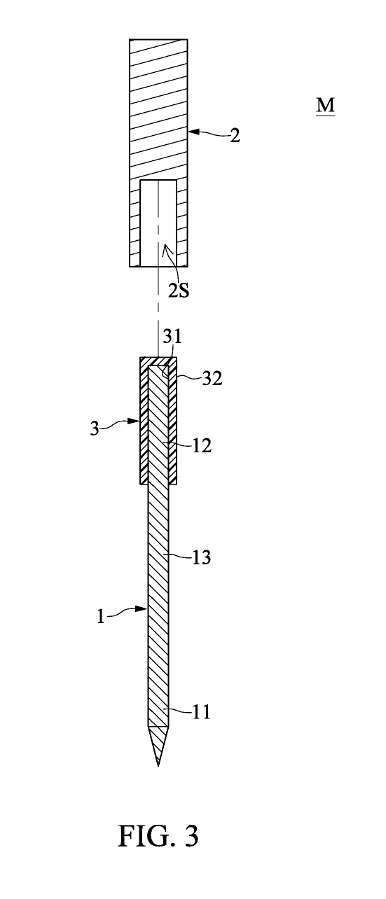

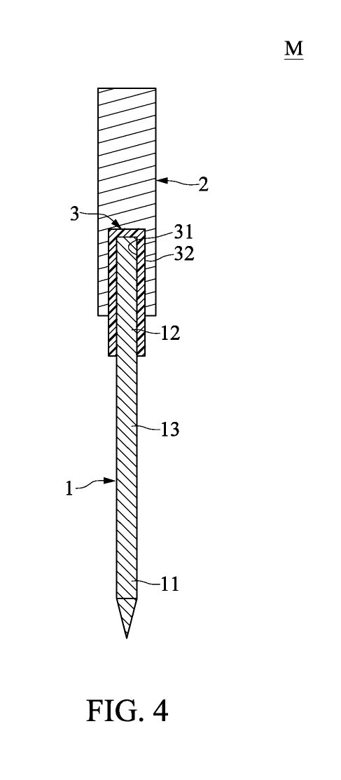

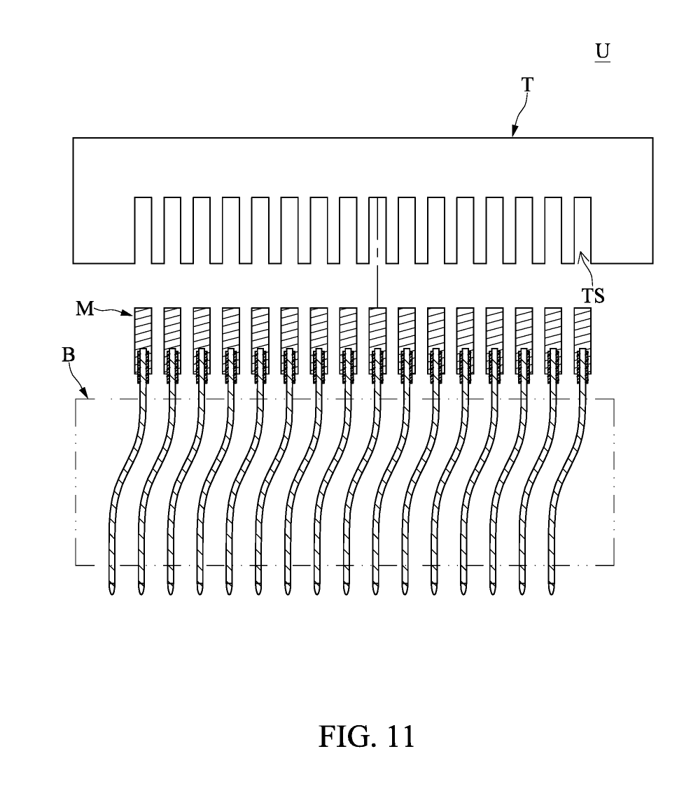

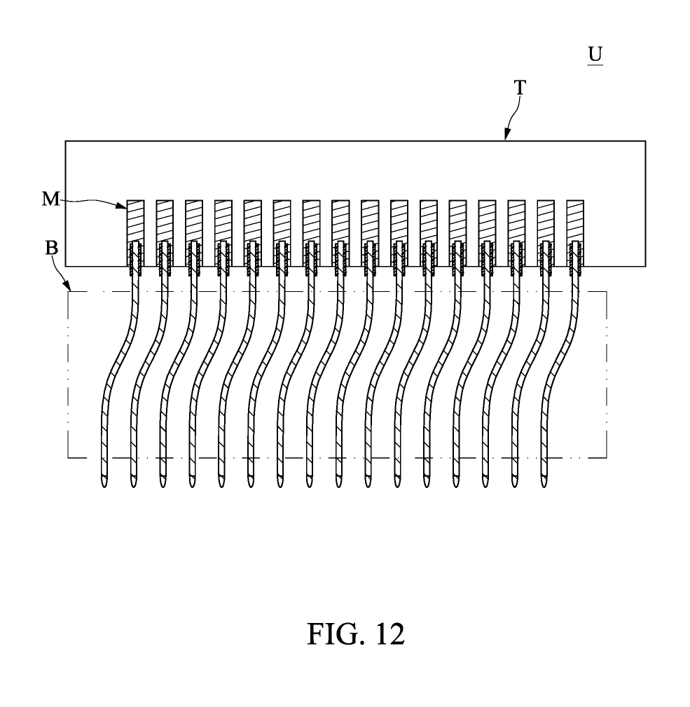

Reference is made to FIG. 1 to FIG. 4, FIG. 11 and FIG. 12. FIG. 1 and FIG. 2 are perspective views of the capacitive probe M of the first embodiment of the instant disclosure, and FIG. 3 and FIG. 4 are schematic cross-sectional views of the capacitive probe M of the first embodiment of the instant disclosure. The instant disclosure provides a probe assembly U and the capacitive probe M thereof. In the first and second embodiments, the features of the capacitive probe M are described, and the details and features of the probe assembly U are described in the third embodiment. In addition, it should be noted that although the capacitive probe M in the figures is depicted as a rectangular column, the shape of the capacitive probe M is not limited in the instant disclosure. In other embodiments, the capacitive probe M can have a cylinder shape or other shapes. Furthermore, it should be noted that although the capacitive probe M are depicted as a linear structure in FIG. 1 to FIG. 10, in other embodiments of the instant disclosure, the capacitive probe M can also have a curved shape such as that shown in FIG. 11 and FIG. 12.

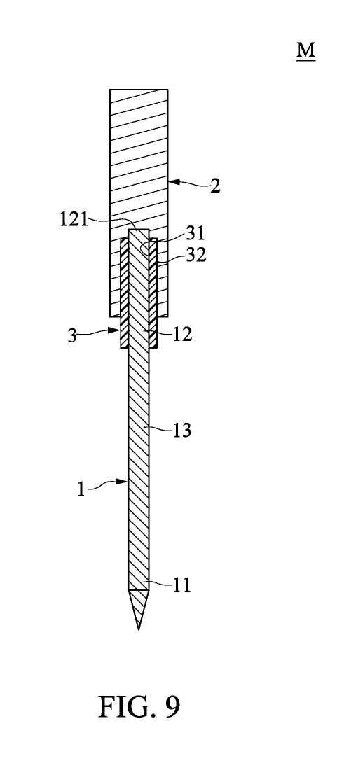

As shown in FIG. 1 to FIG. 4, the capacitive probe M can include a probe structure 1, a conductive structure 2 and a dielectric structure 3. The probe structure 1 can have a first end portion 11, a second end portion 12 corresponding to the first end portion 11, and a connecting portion 13 connected between the first end portion 11 and the second end portion 12. For example, the first end portion 11 of the probe structure 1 can be in a shape of a pointed needle for breaking the oxidation layer on the surface of a tin ball (the object to be measured). However, in other embodiments, the first end portion 11 of the probe structure 1 can have a flat surface; the instant disclosure is not limited thereto. In addition, the second end portion 12 can be a needle tail of the probe structure 1 for being connected to the contacting end of the transferring interface plate (such as the transfer board T in FIG. 9).

The probe structure 1 can be made of conductive material for having conductivity, and the resistivity of the probe structure 1 can be less than 5×10² Ωm. The material for forming the probe structure 1 can include but not limited to: gold (Au), silver (Ag), copper (Cu), nickel (Ni), cobalt (Co) or any alloy thereof. Preferably, the probe structure 1 can be a composite metal material having conductivity, for example, a palladium-nickel alloy, a nickel-cobalt alloy, a nickel-magnesium alloy, a nickel-tungsten alloy, a nickel-phosphor alloy or a palladium-cobalt alloy. In addition, in other implementations, the outer surface of the probe structure 1 can have covering layers made of different materials stacked thereon for forming a probe structure 1 with a multi-layer covering structure (not shown in the figures).

Referring to FIG. 2 and FIG. 4, the conductive structure 2 can be disposed at one side of the probe structure 1 and the dielectric structure 3 can be disposed between the probe structure 1 and the conductive structure 2. In the implementation shown in FIG. 1 to FIG. 4, the conductive structure 2 has an accommodating space 2S, the dielectric structure 3 can be disposed on the second end portion 12 of the probe structure 1 and the second end portion 12 of the probe structure 1, and a part or all of the dielectric structure 3 can be disposed in the accommodating space 2S. In other words, in the implementation shown in FIG. 1 to FIG. 4, the conductive structure 2 is a sleeve-like structure having the accommodating space 2S for accommodating the second end portion 12 of the probe structure 1 and the dielectric structure 3. In addition, the conductive structure 2 has conductivity and a resistivity thereof is less than 5×10² Ωm. For example, the material of the conductive structure 2 can include but not limited to: gold, silver, copper, nickel, cobalt or the alloy thereof. However, the instant disclosure is not limited thereto. Moreover, the conductive structure 2 can be a composite material having conductivity, such as a palladium-nickel alloy, a nickel-cobalt alloy, a nickel-magnesium alloy, a nickel-tungsten alloy, a nickel-phosphor alloy or a palladium-cobalt alloy.

Referring to FIG. 1 and FIG. 2, in the first embodiment of the instant disclosure, the dielectric structure 3 can be disposed between the probe structure 1 and the conductive structure 2 for electrically insulating the probe structure 1 and the conductive structure 2 from each other. In addition, the dielectric structure 3 can have a first surface 31 (inner surface) directly contacting with the probe structure 1, and a second surface (outer surface) directly contacting with the conductive structure 2. For example, the dielectric structure 3 can be made of an insulation material and have a resistivity of more than or equal to 10⁸ Ωm. Preferably, the resistivity of the dielectric structure 3 can be more than or equal to 10⁹ Ωm. In addition, the material of the dielectric structure 3 can include but not limited to polymer materials or ceramic materials, preferably, aluminum oxide (Al₂O₃). Moreover, in other implementations, the material of the dielectric structure 3 can be silicon nitride, yttrium oxide, titanium oxide, hafnium oxide, zirconium oxide or barium titanate. However, the instant disclosure is not limited thereto. Therefore, a capacitive area C can be formed by the dielectric structure 3 disposed between the probe structure 1 and the conductive structure 2, thereby forming an embedded capacitor in the capacitive probe M.

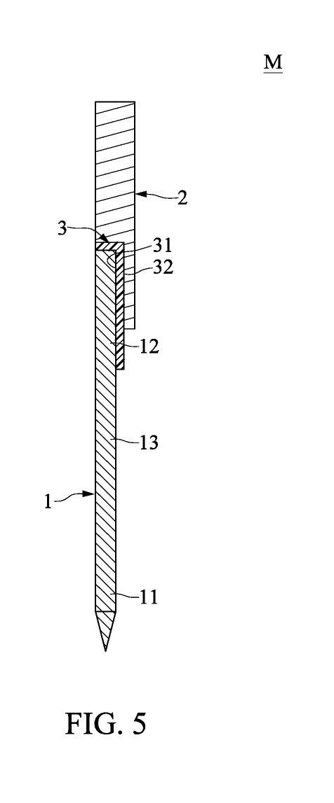

FIG. 5 shows the schematic cross-sectional view of another implementation of the capacitive probe of the first embodiment. Comparing FIG. 5 to FIG. 4, in the implementation shown in FIG. 5, the conductive structure 2 is not a sleeve-like structure. In other words, the conductive structure 2 can be disposed on one side of the probe structure 1 (to be only in contact with the probe structure 1 through the side) or partially surround the side of the probe structure 1 and be disposed on the probe structure 1 through the dielectric structure 3. For example, the arrangement of the probe structure 1, the dielectric structure 3 and the conductive structure 2 can be formed by a microelectromechanical system (MEMS) process such as a lithography process and/or an electroplating process.

In addition, it should be noted that since the dielectric structure 3 is disposed between the probe structure 1 and the conductive structure 2 and covers the second end portion 12 of the probe structure 1 for electrically insulating the probe structure 1 from the conductive structure 2, the probe structure 1, the conductive structure 2 and the dielectric structure 3 in the capacitive probe M provided by the first embodiment of the instant disclosure can be referred to as components connected in series.

### Second Embodiment

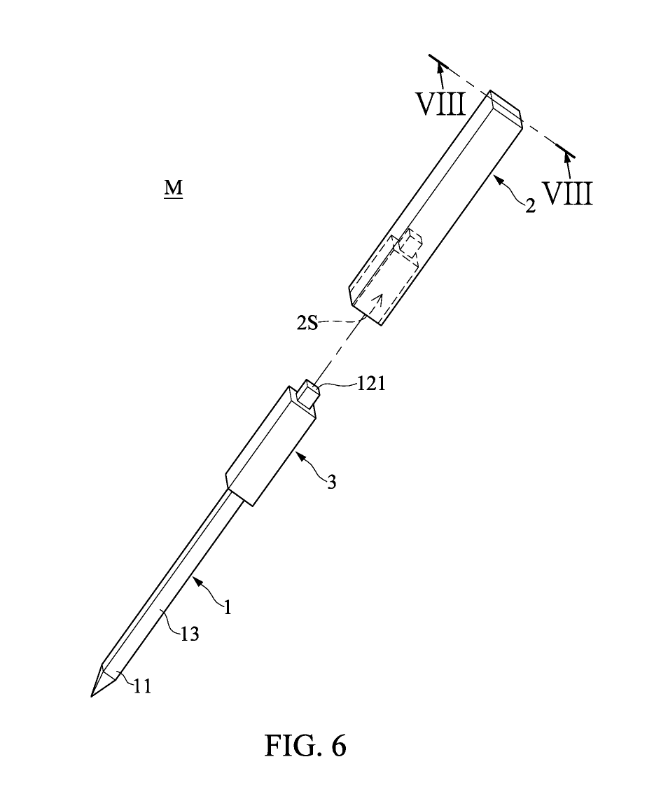

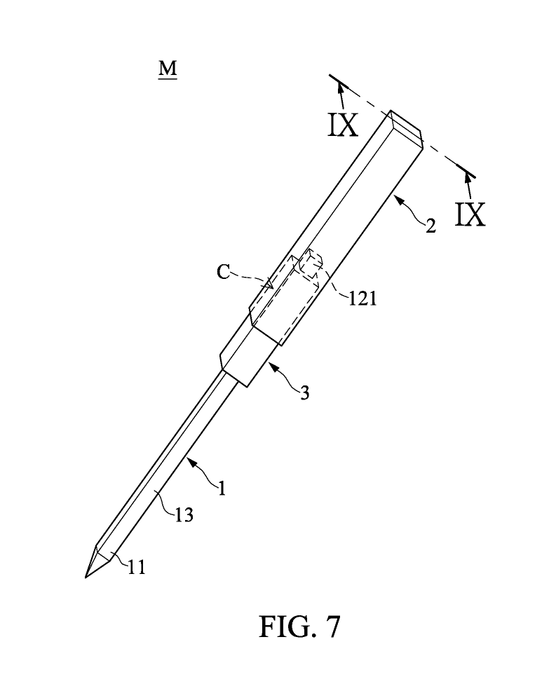

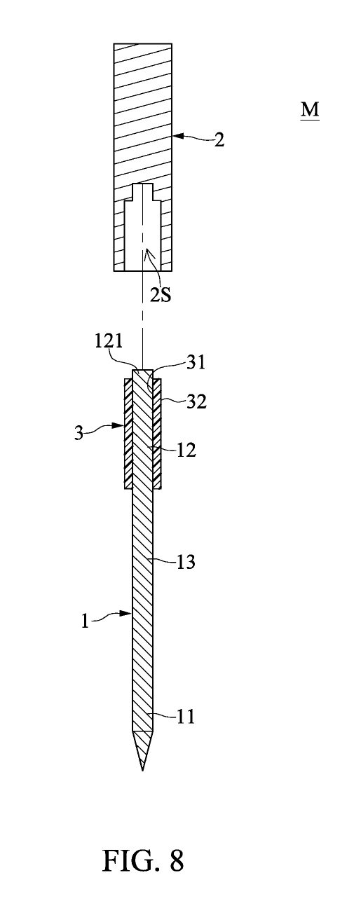

Reference is made to FIG. 6 to FIG. 9. FIG. 6 and FIG. 7 are perspective views of the capacitive probe M of the second embodiment of the instant disclosure, and FIG. 8 and FIG. 9 are the schematic cross-sectional views of the capacitive probe M of the second embodiment of the instant disclosure. Comparing FIG. 9 to FIG. 4, the main difference between the second embodiment and the first embodiment is that the probe structure 1, the conductive structure 2 and the dielectric structure 3 in the capacitive probe M provided by the second embodiment are connected in parallel. In addition, it should be noted that the properties of the probe structure 1, the conductive structure 2 and the dielectric structure 3 in the capacitive probe M provided by the second embodiment are similar to that of the first embodiment and are not reiterated herein. In other words, the resistivity, materials and/or shape of the probe structure 1, the conductive structure 2 and the dielectric structure 3 are similar to that described in the previous embodiment.

Specifically, as shown in FIG. 8 and FIG. 9, the dielectric structure 3 can be disposed on the second end portion 12 of the probe structure 1. The second end portion 12 of the probe structure 1 can have an exposed portion 121 corresponding to the dielectric structure 3, and the probe structure 1 can be electrically connected to the conductive structure 2 through the exposed portion 121. In the implementation shown in FIG. 8 and FIG. 9, the conductive structure 2 is a sleeve-like structure and has an accommodating space 2S for accommodating the second end portion 12 of the probe structure 1 and the dielectric structure 3. In addition, the dielectric structure 3 can have a first surface 31 in contact with the probe structure 1, and a second surface 32 in contact with the second surface 32. In other words, the probe structure 1, the conductive structure 2 and the dielectric structure 3 in the capacitive probe M provided by the second embodiment are connected in parallel.

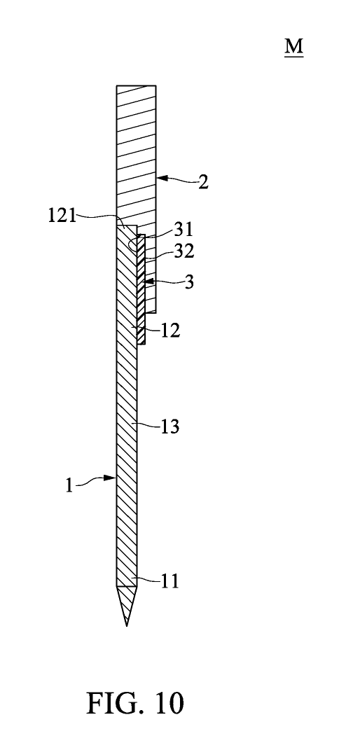

Reference is made to FIG. 10. Comparing FIG. 10 to FIG. 9, it should be noted that the conductive structure 2 is not a sleeve-like structure in the implementation shown in FIG. 10. In other words, the conductive structure 2 can be disposed on one side of the probe structure 1 (to be only in contact with the probe structure 1 through the side) or partially surround the side of the probe structure 1 and be disposed on the probe structure 1 through the dielectric structure 3. For example, the arrangement of the probe structure 1, the dielectric structure 3 and the conductive structure 2 can be formed by a microelectromechanical system (MEMS) process such as a lithography process and/or an electroplating process.

### Third Embodiment

Reference is made to FIG. 11 and FIG. 12. FIG. 11 and FIG. 12 are schematic views of the probe assembly U provided by the embodiment of the instant disclosure. The third embodiment of the instant disclosure provides a probe assembly U including a transfer board T, a probe carrying seat B and a plurality of capacitive probes M. The transfer board T can have a plurality of accommodating grooves TS. The probe carrying seat B can be disposed on the transfer board T, and the plurality of capacitive probes M can be disposed on the probe carrying seat B respectively. In addition, the plurality of capacitive probes M can be disposed in the plurality of accommodating grooves TS. It should be noted that the combination of the transfer board T and the probe carrying seat B is well-known to those skilled in the art and is not described herein.

Reference is made to FIG. 11, FIG. 12 and FIG. 4 to FIG. 9. In the third embodiment of the instant disclosure, the capacitive probes M are the capacitive probes M described in the first embodiment. However, in other implementations, the capacitive probe M provided by the second embodiment can also be used in the third embodiment.

Each of the capacitive probes M includes a probe structure 1, a conductive structure 2 and a dielectric structure 3. The probe structure 1 can have a first end portion 11, a second end portion 12 corresponding to the first end portion 11, and a connecting portion 13 connected between the first end portion 11 and the second end portion 12. The conductive structure 2 can be disposed on one side of the probe structure 1, and the dielectric structure 3 can be disposed between the probe structure 1 and the conductive structure 2. It should be noted that in the third embodiment of the instant disclosure, the conductive structures 2 of each of the capacitive probes M can be electrically connected to the transfer board T for feeding the power and/or the ground voltage to the capacitive probes M. In addition, it should be noted that details regarding the capacitive probe M are already described in the first and second embodiments and are not reiterated herein.

One of the advantages of the instant disclosure resides in that the probe assembly U and the capacitive probe M thereof can optimize the target impedance value and increase the performance of the power delivery network based on the technical feature of “the dielectric structure 3 being disposed between the probe structure 1 and the conductive structure 2”. In addition, since the dielectric structure 3 is disposed on the probe structure 1 and between the probe structure 1 and the conductive structure 2, the design of the dielectric structure 3 can form an embedded capacitor in the capacitive probe M. Moreover, the capacitor in the capacitive probe M can achieve the object of optimizing the target impedance value compared to the structure of the existing art, in which the transfer board (transfer substrate) is relatively far from the end to be measured, so that the parasitic effect can be improved.

The above-mentioned descriptions represent merely the exemplary embodiment of the present disclosure, without any intention to limit the scope of the instant disclosure thereto. Various equivalent changes, alterations or modifications based on the claims of the instant disclosure are all consequently viewed as being embraced by the scope of the instant disclosure.

What is claimed is:

1. A capacitive probe, comprising:
a probe structure having a first end portion, a second end portion corresponding to the first end portion, and a connecting portion connected between the first end portion and the second end portion;
a conductive structure disposed at one side of the probe structure; and
a dielectric structure disposed between the probe structure and the conductive structure.

2. The capacitive probe according to claim 1, wherein the conductive structure has an accommodating space, the dielectric structure is disposed on the second end portion of the probe structure, and the second end portion of the probe structure and the dielectric structure are disposed in the accommodating space.

3. The capacitive probe according to claim 2, wherein the second end portion of the probe structure has an exposed portion corresponding to the dielectric structure, and the probe structure is electrically connected to the conductive structure through the exposed portion, wherein the dielectric portion has a first surface in contact with the probe structure and a second surface in contact with the conductive structure.

4. The capacitive probe according to claim 2, wherein the probes structure and the conductive structure are electrically insulated from each other and the dielectric structure has a first surface in contact with the probe structure and a second surface in contact with the conductive structure.

5. The capacitive probe according to claim 2, wherein the conductive structure is a sleeve-like structure.

6. The capacitive probe according to claim 2, wherein the probe structure has a resistivity of less than 5×10² Ωm.

7. The capacitive probe according to claim 2, wherein the conductive structure has a resistivity of less than 5×10² Ωm.

8. The capacitive probe according to claim 2, wherein the dielectric structure has a resistivity of more than or equal to 10⁸ Ωm.

9. A probe assembly, comprising:
a transfer board having a plurality of accommodating grooves;
a probe carrying seat disposed on the transfer board; and
a plurality of capacitive probes disposed on the probe carrying seat, the plurality of capacitive probes being respectively disposed in the plurality of accommodating grooves, wherein each of the capacitive probes includes a probe structure, a conductive structure and a dielectric structure;
wherein the conductive structures of each of the capacitive probes are electrically connected to the transfer board, the probe structure has a first end portion, a second end portion corresponding to the first end and a connecting portion connected between the first end portion and the second end portion, the conductive structure is disposed at one side of the probe structure, and the dielectric structure is disposed between the probe structure and the conductive structure.

10. The probe assembly according to claim 9, wherein the conductive structure has an accommodating space, the dielectric structure is disposed on the second end portion of the probe structure, and the second end portion of the probe structure and the dielectric structure are disposed in the accommodating space.

11. The probe assembly according to claim 10, wherein the second end portion of the probe structure has an exposed portion corresponding to the dielectric structure, and the probe structure is electrically connected to the conductive structure through the exposed portion, wherein the dielectric portion has a first surface in contact with the probe structure and a second surface in contact with the conductive structure.

12. The probe assembly according to claim 10, wherein the probe structure and the conductive structure are electrically insulated from each other, and the dielectric structure has a first surface in contact with the probe structure and a second surface in contact with the conductive structure.
